(19) United States
(12) Patent Application Publication
(10) Pub. No.: US 2026/0118169 A1
(43) Pub. Date: Apr. 30, 2026

(54) Resettable Photon Number Resolving Detector

(71) Applicant: PsiQuantum Corp., Palo Alto, CA (US)

(72) Inventors: Avishai BENYAMINI, Palo Alto, CA (US); Sandeep Kumar SOMAVAPRAPU, Fremont, CA (US); Brad A.J. MOORES, Boulder, CA (US); Faraz NAJAFI, San Francisco, CA (US)

(21) Appl. No.: 19/065,981

(22) Filed: Feb. 27, 2025

Related U.S. Application Data
(63) Continuation of application No. PCT/US2023/032013, filed on Sep. 5, 2023.
(60) Provisional application No. 63/404,104, filed on Sep. 6, 2022.

(51) Int. Cl. G01J 1/44; G01J 1/04; H10N 60/84

(52) U.S. Cl. CPC G01J 1/44; G01J 1/0407; H10N 60/84; G01J 2001/442

(57) ABSTRACT

The various embodiments described herein include methods, devices, and systems for detecting photons. In one aspect, an electrical circuit includes a superconducting photon detector that transitions from a superconducting state to a non-superconducting state in response to an incident photon; and a reset circuit coupled in parallel with the superconducting photon detector, the reset circuit comprising a resistor and an inductor coupled together in series, where the resistor is composed of a metal layer and a layer of superconducting material.

### RELATED APPLICATIONS

This application is a continuation of PCT Patent Application No. PCT/US2023/032013, filed Sep. 5, 2023, which claims priority to U.S. Provisional Patent Application No. 63/404,104, entitled “PHOTON NUMBER RESOLVING DETECTOR” filed Sep. 6, 2022, each of which is hereby incorporated by reference in its entirety.

### TECHNICAL FIELD

This relates generally to photon detectors, including but not limited to, superconducting photon detectors.

### BACKGROUND

Photon detectors are key components in many electronic devices. Ultra-sensitive photon detectors capable of detecting individual photons (e.g., single photons) can be used in a variety of applications, such as optical communications, medical diagnostics, space research, and optical quantum information computing.

Superconductors are materials capable of operating in a superconducting state with zero electrical resistance under particular conditions. Manipulation of the zero electrical resistance can lead to photon detectors based on superconductors having sensitivity to individual photons.

### SUMMARY

Utilizing superconductor(s) to implement logical and readout circuit(s) allows the circuit(s) to operate at cryogenic temperatures and at nanoscale sizes. From a different perspective, implementing such circuits utilizing superconductors or one or more superconductor elements allows such circuits to benefit from the properties of superconductors. For example, such devices would be beneficial for low-latency operations directly on a cryogenic chip.

In one aspect, some embodiments include an electrical circuit. The electrical circuit includes: a superconducting photon detector that transitions from a superconducting state to a non-superconducting state in response to an incident photon; and a reset circuit coupled in parallel with the superconducting photon detector, the reset circuit comprising a resistor (R) and an inductor (L) coupled together in series, where the resistor is composed of a metal layer and a layer of superconducting material.

In another aspect, some embodiments include a photon number resolving circuit. The photon number resolving circuit includes a plurality of detection circuits, each detection circuit of the plurality of detection circuits including: a superconducting photon detector that transitions from a superconducting state to a non-superconducting state in response to an incident photon; and a reset circuit coupled in parallel with the superconducting photon detector, the reset circuit including a resistor (R) and an inductor (L) coupled together in series. The photon number resolving circuit further includes a waveguide optically coupled to the plurality of detection circuits; and a readout circuit electrically coupled to the plurality of detection circuits.

Thus, superconducting devices and systems are provided with methods for detecting photons and resolving photon detection numbers, thereby increasing accuracy, effectiveness, efficiency, and user satisfaction. Such systems, devices, and methods optionally complement or replace conventional systems, devices, and methods for detecting photons and/or resolving photon detection numbers.

### BRIEF DESCRIPTION OF THE DRAWINGS

For a better understanding of the various described embodiments, reference should be made to the Detailed Description below, in conjunction with the following drawings in which like reference numerals refer to corresponding parts throughout the figures.

FIG. 1 is a schematic diagram illustrating an example photon detection circuit in accordance with some embodiments.

FIG. 2 is a schematic diagram illustrating another example photon detection circuit in accordance with some embodiments.

FIGS. 3A-3B are prophetic diagrams illustrating a representative operating sequence of the photon detection circuit of FIG. 2 in accordance with some embodiments.

FIG. 4 is a schematic diagram illustrating an example detector unit cell in accordance with some embodiments.

FIG. 5A shows an example layout for the detector unit cell of FIG. 4 in accordance with some embodiments.

FIG. 5B shows an example cross-sectional view for the resistive region of FIG. 5A in accordance with some embodiments.

FIG. 5C shows another example cross-sectional view for the resistive region of FIG. 5A in accordance with some embodiments.

FIG. 5D is a block diagram illustrating an example superconducting stack in accordance with some embodiments.

FIG. 5E is a block diagram illustrating an example conductive stack in accordance with some embodiments.

FIG. 6 shows an example layout for a photon number resolving detector in accordance with some embodiments.

FIG. 7A is a schematic diagram illustrating an example photon number resolving circuit in accordance with some embodiments.

FIGS. 7B-7D are prophetic diagrams illustrating a representative operating sequence of the photon number resolving circuit of FIG. 7A in accordance with some embodiments.

FIG. 8A is a schematic diagram illustrating an example readout circuit for the photon number resolving circuit of FIG. 7A in accordance with some embodiments.

FIG. 8B is a schematic diagram illustrating another example readout circuit for the photon number resolving circuit of FIG. 7A in accordance with some embodiments.

### DETAILED DESCRIPTION

Reference will now be made in detail to embodiments, examples of which are illustrated in the accompanying drawings. In the following detailed description, numerous specific details are set forth in order to provide a thorough understanding of the various described embodiments. However, it will be apparent to one of ordinary skill in the art that the various described embodiments may be practiced without these specific details. In other instances, well-known methods, procedures, components, circuits, and networks have not been described in detail so as not to unnecessarily obscure aspects of the embodiments.

Many modifications and variations of this disclosure can be made without departing from its spirit and scope, as will be apparent to those skilled in the art. The specific embodiments described herein are offered by way of example only, and the disclosure is to be limited only by the terms of the appended claims, along with the full scope of equivalents to which such claims are entitled.

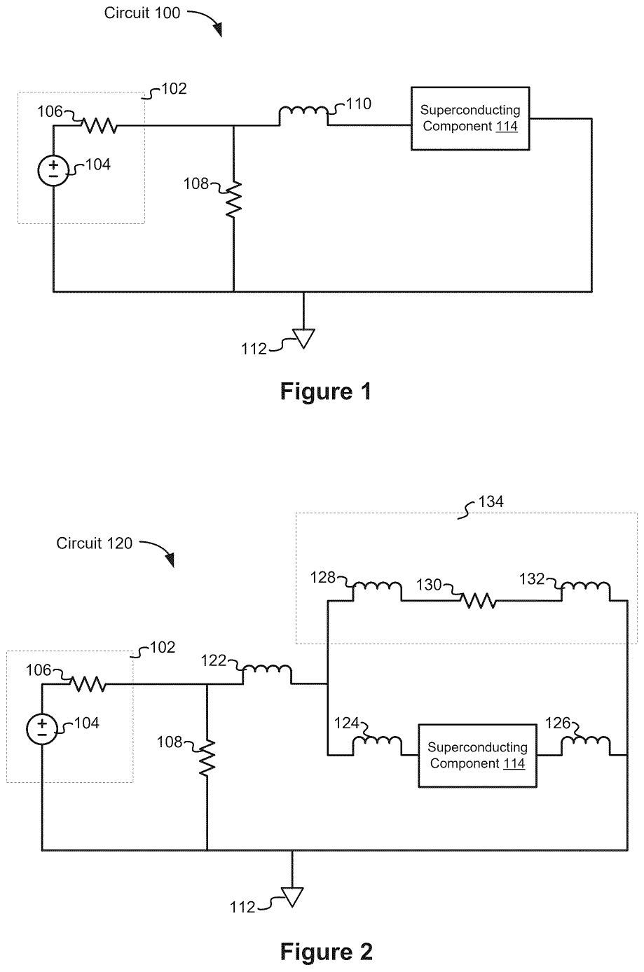

FIG. 1 is a schematic diagram illustrating a photon detection circuit 100 in accordance with some embodiments. The photon detection circuit 100 includes a superconducting component 114, an inductor 110, a resistor 108, an electrical ground 112, and a current source 102. In accordance with some embodiments, the current source 102 is a direct current (DC) source including a voltage source 104 and a resistor 106. In some embodiments, the current source 102 is configured to supply a current to the superconducting component 114 that biases the superconducting component 114 in the superconducting state in the absence of any incident photons. In operation, current from the current source 102 flows through the superconducting component 114 to the electrical ground 112 while the superconducting component 114 is in the superconducting state.

In some embodiments, the superconducting component 114 is a superconducting nanowire single photon detector (SNSPD). For example, the superconducting component 114 is adapted, and biased, to operate in a superconducting state in the absence of any incident photons. In this example, in response to an incident photon, the superconducting component 114 transitions from the superconducting state to a non-superconducting (e.g., resistive) state. In the superconducting state, the superconducting component 114 has zero resistance. In the non-superconducting state, the superconducting component 114 has a resistance of at least 1 kiloohm (e.g., 5 kiloohms or 10 kiloohms). After transitioning to the non-superconducting state, the superconducting component requires a certain amount of time to transition back to the superconducting state, e.g., a reset time (T). In some embodiments, the superconducting component has an associated reset time in the range of 0.5 nanoseconds to 5 nanoseconds (e.g., 1 nanosecond).

The resistor 108 represents an inherent resistance of a readout circuit in accordance with some embodiments. In some embodiments, the resistor 108 has a resistance in the range of 20 ohms to 100 ohms (e.g., 50 ohms). To continue the example above, in response to the superconducting component 114 transitioning to the non-superconducting state, at least a portion of the current from the current source 102 is redirected to flow through the resistor 108 to the electrical ground 112. The inductor 110 is adapted (e.g., sized) to delay current from returning to the superconducting component 114 until at least the reset time (T) has elapsed (e.g., where the reset time is an amount of time elapsed, beginning when the superconducting component 114 transitions to the non-superconducting state, until current returns to the superconducting component 114). In some embodiments, the inductor 110 has an inductance in the range of 50 nanohenries to 200 nanohenries (e.g., 100 nanohenries). For example, the resistor 108 has a resistance of 50 ohms and the inductor 110 has an inductance of 100 nanohenries, resulting in an RL time constant of 2 nanoseconds (e.g., L/R=time constant, with L measured in Henries, R measured in Ohms, and the time constant expressed in units of seconds).

In some embodiments, the inductor 110 has a kinetic inductance in the range of 50 nanohenries to 200 nanohenries (e.g., 100 nanohenries). As used herein, kinetic inductance is an inductance per square of material. In some embodiments, the inductor 110 is composed of a superconducting material (e.g., Niobium nitride). In some embodiments, the superconducting material has a per square kinetic inductance in the range of 10 picohenries to 200 picohenries (e.g., 100 picohenries). In some embodiments, the superconducting material has a per square kinetic inductance of less than 1 nanohenry while in the superconducting state and a negligible per square kinetic inductance (e.g., less than 1 picohenry) while in the non-superconducting state. For example, the inductor 110 has a kinetic inductance of 100 nanohenries and is composed of 1000 squares of superconducting material, e.g., has a width of 200 nanometers and a length of 2000 microns.

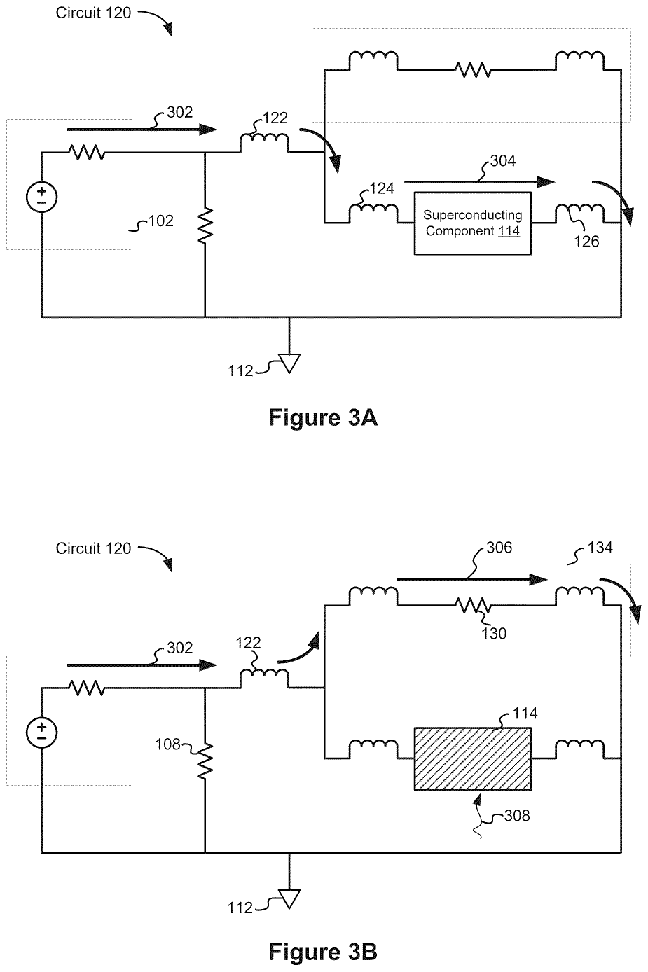

FIG. 2 is a schematic diagram illustrating a photon detection circuit 120 in accordance with some embodiments. The photon detection circuit 120 includes the superconducting component 114, the current source 102, the resistor 108, the electrical ground 112, and a reset circuit 134. The photon detection circuit 120 further includes inductors 122, 124, and 126. In some embodiments, the inductors 122, 124, and 126 represent kinetic inductance of wires in the photon detection circuit 120. In some embodiments, the inductors 122, 124, and 126 each have an inductance of less than 10 nanohenries (e.g., have an inductance less than 5, 2, or 1 nanohenry). In some embodiments, the inductors 122, 124, and 126 each have an inductance of less than 1 nanohenry (e.g., have an inductance less than 0.5, 0.2, or 0.1 nanohenry).

In accordance with some embodiments, the reset circuit 134 includes inductors 128 and 132 and resistor 130. In some embodiments, the reset circuit 134 is configured to have an RL time constant of at least the reset time (T) of the superconducting component 114. In some embodiments, the resistor 130 has a resistance of less than 10 ohms (e.g., has a resistance of less than 5, 2, or 1 ohm). In some embodiments, the resistor 130 has a resistance in the range of 0.1 ohm to 1000 ohms. In some embodiments, the resistor 130 is composed of a conductive material (e.g., a metal) and a superconductive material (e.g., Niobium nitride). In some embodiments, the inductors 128 and 132 represent kinetic inductance of wires in the reset circuit 134. In some embodiments, the inductors 128 and 132 each have an inductance of less than 10 nanohenries (e.g., have an inductance less than 5, 2, or 1 nanohenry). In some embodiments, the inductors 128 and 132 each have an inductance of less than 1 nanohenry (e.g., have an inductance less than 0.5, 0.2, or 0.1 nanohenry). In some embodiments, the reset circuit 134 has an RL time constant that is at least the reset time period (T) of the superconducting component 114. In some embodiments, the reset circuit 134 has an RL time constant between 0.5 nanoseconds and 10 nanoseconds (e.g., a time constant of 1 nanosecond). For example, the resistor 130 has a resistance of 1 ohm and the inductors have a combined inductance of 1 nanohenry, resulting in an RL time constant of 1 nanosecond.

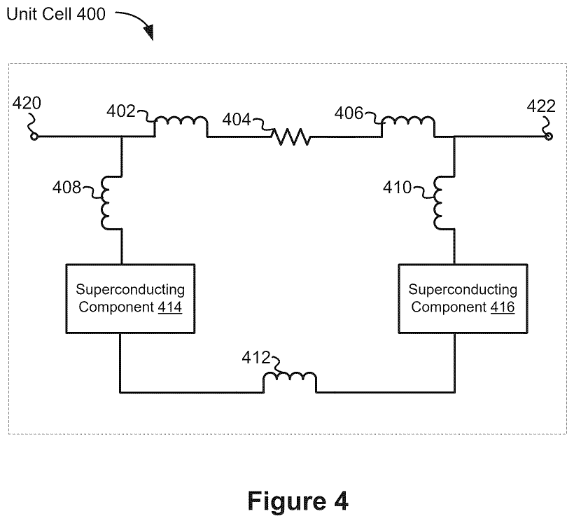

FIGS. 3A-3B are prophetic diagrams illustrating a representative operating sequence of the photon detection circuit 120 (e.g., the photon detection circuit 120 in FIG. 2) in accordance with some embodiments. FIG. 3A shows current flow at a first time when the superconducting component 114 is in a superconducting state. As shown in FIG. 3A, all, or a majority of, the current 302 from the current source 102 flows through the superconducting component branch of the circuit. Specifically, the current flows from the current source 102 through the inductors 122, 124, and 126 as well as flowing through the superconducting component 114 to the electrical ground 112. The current 304 in FIG. 3A represents all, or a majority of, the current 302 from the current source 102, because the superconducting component branch of the circuit has the least resistance (e.g., due to the superconducting component 114 having zero resistance while in the superconducting state).

FIG. 3B shows current flow at a second time when the superconducting component 114 is in a non-superconducting state. The superconducting component 114 is in the non-superconducting state due to an incident photon 308 being absorbed by the superconducting component 114, in accordance with some embodiments. As shown in FIG. 3B, a majority of the current 302 from the current source 102 flows through the reset branch of the circuit. Specifically, the current flows from the current source 102 through the inductor 122 and the reset circuit 134 to the electrical ground 112. The current 306 in FIG. 3B represents a majority of the current 302 from the current source 102, because the reset branch of the circuit has the least resistance. For example, the reset branch has a resistance of 1 ohm (e.g., due to the resistor 130), whereas the superconducting component 114 has a resistance of 10 kiloohms (while in the non-superconducting state) and the resistor 108 has a resistance of 50 ohms.

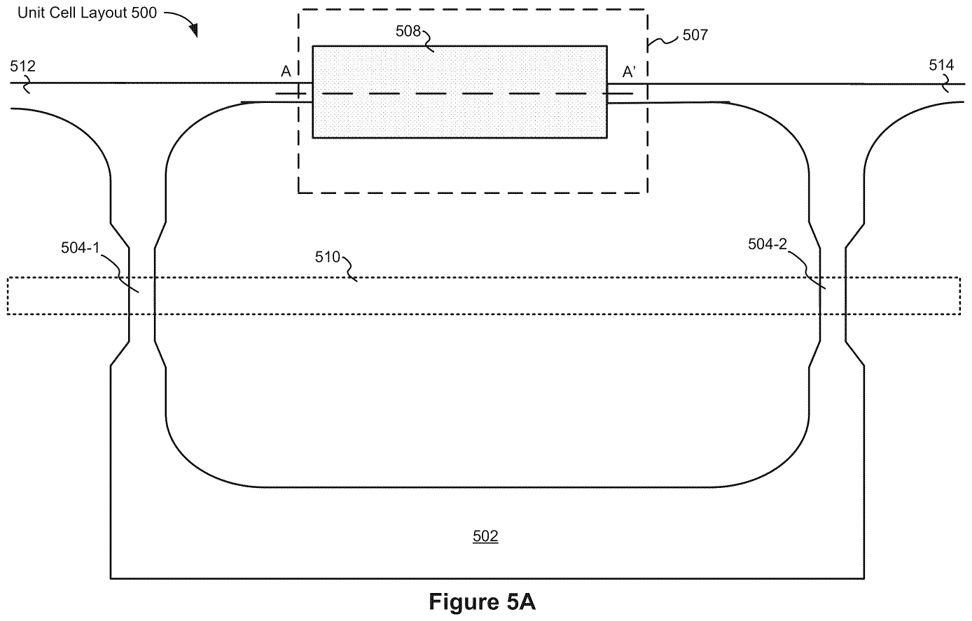

FIG. 4 is a schematic diagram illustrating a detector unit cell 400 in accordance with some embodiments. The detector unit cell 400 includes superconducting components 414 and 416, inductors 402, 406, 408, 410, and 412, and resistor 404. In some embodiments, the superconducting components 414 and 416 each represent an SNSPD. In some embodiments, the superconducting components 414 and 416 are instances of the superconducting component 114. In some embodiments, the superconducting components 414 and 416 have the same properties, e.g., have the same reset time and resistance when in the non-superconducting state. In some embodiments, the superconducting components 414 and 416 are distinct from one another (e.g., have different reset times, resistances, etc.).

In some embodiments, connection point 420 is coupled to a current source (e.g., the current source 102). In some embodiments, connection point 422 is coupled to an electrical ground (e.g., the electrical ground 112). As an example operating sequence, at a first time the superconducting components 414 and 416 are in the superconducting state and have zero resistance. Therefore, at the first time, all (or a majority of) current from the current source flows through the superconducting components 414, 416 to the electrical ground. To continue the example operating sequence, at a second time that is after the first time, one (or both) of the superconducting components 414, 416 is in a non-superconducting state (e.g., due to an incident photon). Furthermore, in some embodiments, superconducting components 414 and 416, which are connected in series, when in the non-superconducting state have a total resistance that is at least ten times the resistance of resistor 404 (e.g., have a resistance that is at least 10, 20, 50 or 100 times the resistance of resistor 404). For example, superconducting components 414 and 416, when in the non-superconducting state have a total resistance of at least 1 kiloohm, while resistor 404 has a resistance of 100 ohms or less, or 10 ohms or less. Therefore, at the second time, a majority of the current from the current source flows through the resistor 404 to the electrical ground.

In some embodiments, the inductors 402, 406, 408, 410, and 412 are kinetic inductances (e.g., represent inductances inherent in the wires). In some embodiments, the inductors 402, 406, 408, 410, and 412 are composed of superconducting material (e.g., a same superconducting material as the superconducting components 414 and 416). In some embodiments, the inductors 402, 406, 408, 410, and 412 each have a same inductance, within a predefined tolerance, such as 5 percent, 10 percent or 20 percent. For example, each of the inductors 402, 406, 408, 410, and 412 represent wires having the same number of squares of material. In some embodiments, at least a subset of the inductors 402, 406, 408, 410, and 412 have differing inductances. For example, a subset of the inductors 402, 406, 408, 410, and 412 represent wires that are longer or wider than others of the inductors. In some embodiments, the combination of the inductors 402 and 406 and the resistor 404 represents a reset circuit (e.g., the reset circuit 134) for the superconducting components 414 and 416. In some embodiments, the resistor 404 is an instance of the resistor 130 described above. In some embodiments, the unit cell 400 has an RL time constant that is greater than the reset time of either of the superconducting components 414 and 416.

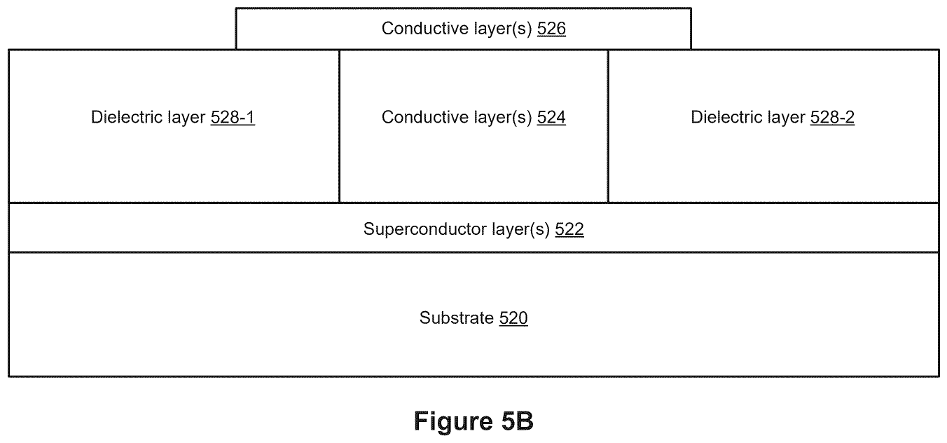

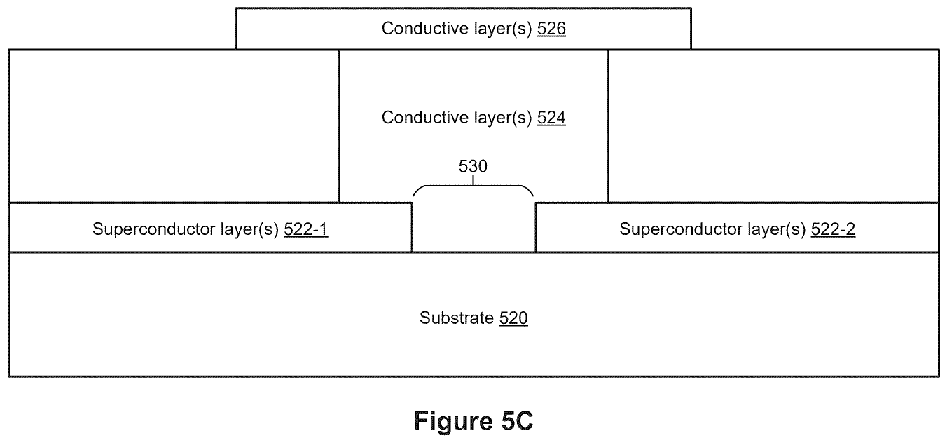

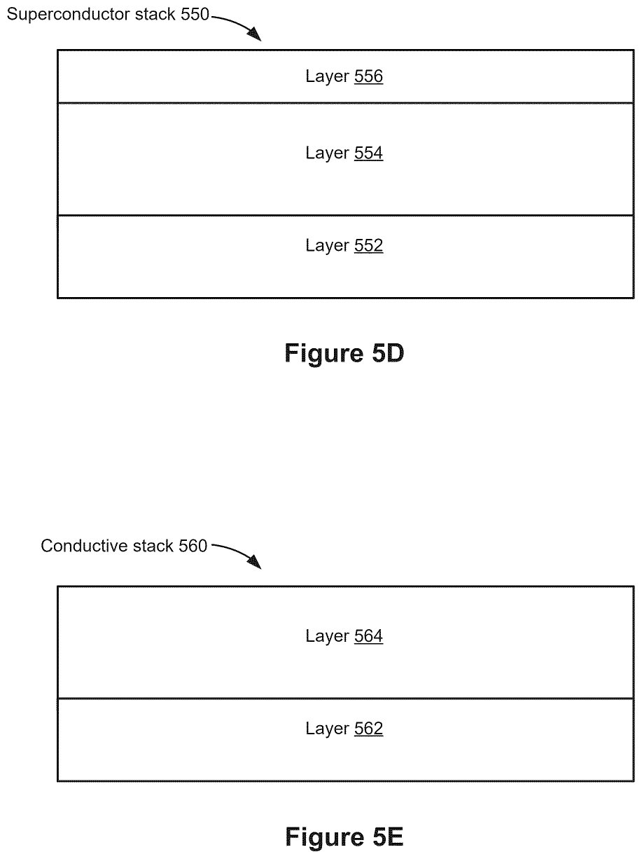

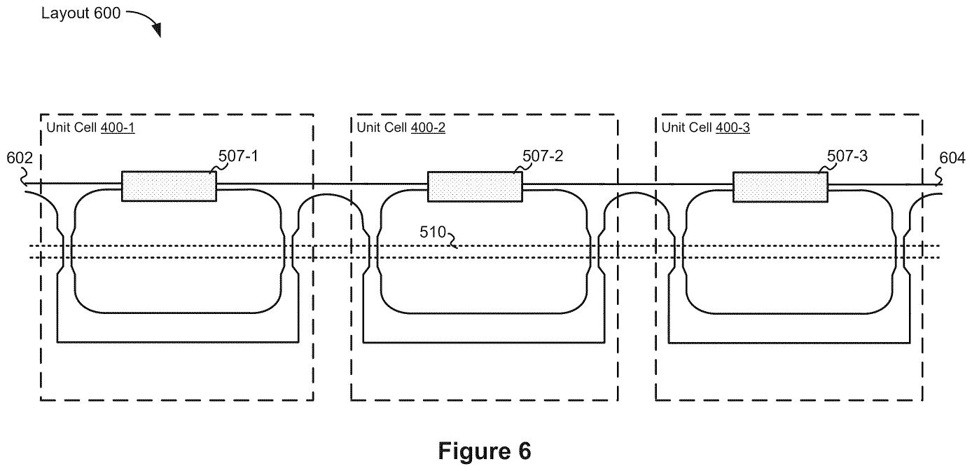

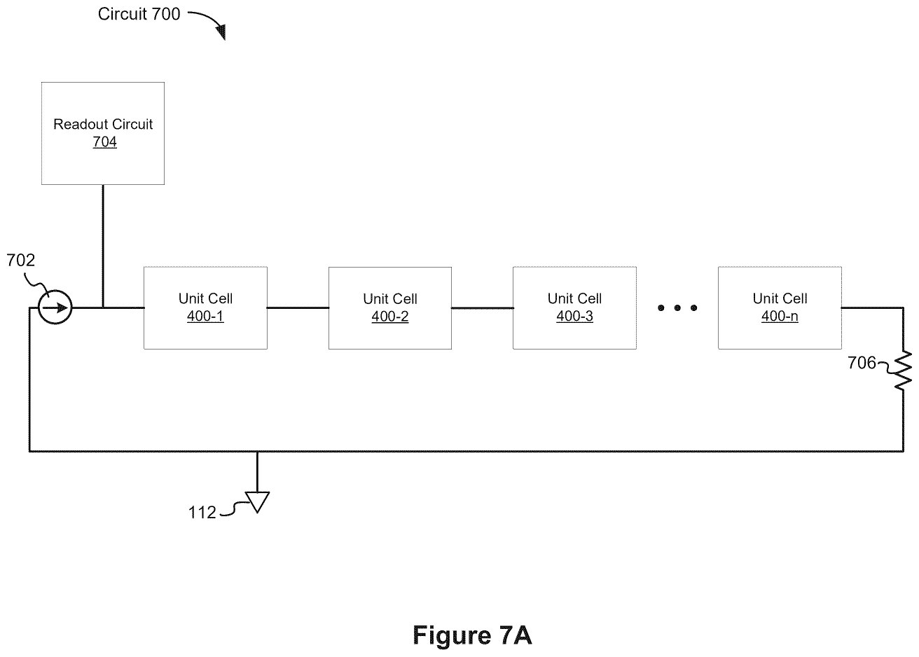

FIG. 5A shows a layout 500 for the detector unit cell 400 in accordance with some embodiments. The layout 500 includes a superconducting material 502 (e.g., Niobium nitride) having narrow portions 504 for the superconducting components. For example, narrow portion 504-1 corresponds to superconducting component 414 and narrow portion 504-2 corresponds to superconducting component 416. The layout 500 further includes a waveguide 510 overlapping to the narrow portions 504. In accordance with some embodiments, photons traveling within the waveguide 510 transfer to one of the narrow portions 504 (e.g., become incident photons to one of the narrow portions 504).

The layout 500 further includes a resistive region 507 (e.g., corresponding to the resistor 404 in FIG. 4). The resistive region 507 in the layout 500 includes a conductive material 508 that is, or includes, a metal (e.g., copper (Cu), aluminum (Al), tungsten (W), or gold (Au)). Although FIG. 5A shows the conductive material 508 above the superconducting material 502, in some embodiments, the conductive material 508 is on another side of the superconducting material 502 (e.g., below the superconducting material or next to the superconducting material). In accordance with some embodiments, the resistive region has a length and/or width in the range of 5 nanometers to 5000 nanometers. In some embodiments, the superconducting material 502 has a width in the range of 5 nanometers to 5000 nanometers.

In some embodiments, the resistive region 507 is configured to have a resistance in the range of 0.1 ohms to 1000 ohms. In some embodiments, the resistance of the resistive region 507 in the layout 500 is, or includes, the resistance of the conductive material 508. In some embodiments, the resistance of the resistive region 507 is a proximity resistance. As used herein, a proximity resistance is a resistance introduced into the superconducting material due to the proximity of the conductive material. In some embodiments, the resistance is introduced into the superconducting material due to electrical contact between the conductive material and the superconducting material.

In some embodiments, the end 512 of the superconducting material is coupled to a current source. In some embodiments, the end 514 of the superconducting material is coupled to an electrical ground. When the detector unit cell is operated at temperatures below a critical temperature for the superconducting components and is biased by a biasing current for photon detection, photons that transfer to a respective narrow portion 504 cause the respective narrow portion to transition from the superconducting state to the non-superconducting state. As an example operating sequence, at a first time the narrow portions 504 are in the superconducting state and have zero resistance. Therefore, at the first time, all (or a majority of) current from the current source flows through the narrow portions 504 to the electrical ground. To continue the example operating sequence, at a second time, one (or both) of the narrow portions 504 is in a non-superconducting state, e.g., due to an incident photon from the waveguide 510. Therefore, at the second time, a majority of the current from the current source flows through the resistive region 507 to the electrical ground.

FIG. 5B shows cross-sectional view A-A′ for the resistive region 507 of FIG. 5A in accordance with some embodiments. As shown in FIG. 5B, the resistive region 507 includes a substrate 520, one or more superconductor layers 522, one or more conductive layers 524, one or more conductive layers 526, and dielectric layers 528-1 and 528-2. In some embodiments, the conductive layer(s) 526 are configured and/or arranged to provide an electrical contact for conductive layer(s) 524 (e.g., to electrically couple the conductive layer(s) 524 to one or more electrical components). In some embodiments, the conductive layer(s) 526 are configured and/or arranged to protect the conductive layer(s) 524 (e.g., protection from subsequent fabrication steps and/or oxidation). In some embodiments, the conductive layer(s) 526 are configured and/or arranged to provide electrical tuning for conductive layer(s) 524 (e.g., adjust one or more electrical properties of conductive layer(s) 524).

Because the one or more superconductor layers 522 are continuous in the layout of FIG. 5B, current flowing through the superconducting material may not flow through to the one or more conductive layers 524 (e.g., all, or a majority of, the current flows through the superconducting material layers without flowing through the one or more conductive layers 524). In some embodiments, the proximity of the conductive material to the superconductor layer(s) 522 introduces a resistance into the superconducting material.

In some embodiments, the substrate 520 is composed of a dielectric material (e.g., bulk Silicon). In some embodiments, the superconductor layer(s) 522 are composed of Niobium nitride. In some embodiments, the superconductor layer(s) 522 have a thickness in the range of 1 nanometer to 20 nanometers (e.g., 5 nm). In some embodiments, the dielectric layers 528 are composed of silicon (e.g., amorphous silicon, silicon dioxide, and/or silicon nitride) and/or aluminum (e.g., aluminum nitride). In some embodiments, the dielectric layers 528 have a thickness in the range of 1 nanometer to 50 nanometers (e.g., 10 nanometers).

In some embodiments, the one or more conductive layers 524 include one or more metal layers (e.g., one or more layers composed of a metallic material). In some embodiments, the one or more conductive layers 524 have a thickness in the range of 0.2 nanometers to 22 microns. In some embodiments, the one or more conductive layers 526 include one or more metal layers (e.g., one or more layers composed of a metallic material). In some embodiments, the one or more conductive layers 526 have a thickness in the range of 0.2 nanometers to 5.2 microns.

FIG. 5C shows another cross-sectional view A-A′ for the resistive region 507. FIG. 5C shows the same layers as described above with respect to FIG. 5B. However, the layout shown in FIG. 5C includes a discontinuity 530 in the one or more superconductor layers 522. In the embodiments shown in FIG. 5C, the one or more conductive layers 524 are positioned in the discontinuity 530 (e.g., the one or more conductive layers 524 are deposited into the discontinuity 530). Due to the discontinuity 530, current flows from the superconductor layer(s) 522 to the conductive layer(s) 524. For example, current flowing through the superconducting layer(s) 522-1 flows to the conductive layer(s) 524 and then to the superconducting layer(s) 522-2 (or vice versa).

FIG. 5D is a block diagram illustrating a superconducting stack 550 in accordance with some embodiments. In accordance with some embodiments, the superconducting stack 550 includes one or more layers. In FIG. 5D, the superconducting stack 550 includes a layer 552, a layer 554, and a layer 556. In some embodiments, the layer 554 is composed of niobium (e.g., niobium nitride), iron (e.g., iron pnictide), vanadium (e.g., vanadium silicide), copper oxide (e.g., LB-CO), and/or magnesium (e.g., magnesium diboride). In some embodiments, the layer 554 has a thickness in the range of 0.2 nanometers to 200 nanometers. In some embodiments, the one or more superconductor layers 522 are an instance of the superconducting stack 550.

In some embodiments, the layer 552 and/or layer 556 are non-superconductive layers (e.g., dielectric layers, conductive layers, and/or composed of other non-superconductive materials). In some embodiments, the layer 552 is composed of silicon (e.g., silicon nitride or silicon dioxide) and/or aluminum (e.g., aluminum nitride). In some embodiments, the layer 552 has a thickness in the range of 0.2 nanometers to 200 nanometers. In some embodiments, the layer 556 is composed of silicon (e.g., amorphous silicon) and/or aluminum (e.g., aluminum nitride). In some embodiments, the layer 556 has a thickness in the range of 0.2 nanometers to 200 nanometers. In some embodiments, the superconducting stack 550 includes more or less layers than shown in FIG. 5D (e.g., only includes the layer 554).

FIG. 5E is a block diagram illustrating a conductive stack 560 in accordance with some embodiments. In accordance with some embodiments, the conductive stack 560 includes one or more layers. In FIG. 5E, the conductive stack 560 includes a layer 562 and a layer 564. In some embodiments, the layer 562 is composed of titanium. In some embodiments, the layer 562 has a thickness in the range of 0.2 nanometers to 200 nanometers. In some embodiments, the layer 564 is composed of copper, aluminum, tungsten, and/or gold. In some embodiments, the layer 564 has a thickness in the range of 0.2 nanometers to 20 microns (e.g., 5 microns). In some embodiments, the conductive stack 560 includes more or less layers than shown in FIG. 5E (e.g., only includes the layer 564). In some embodiments, the one or more conductive layers 524 are an instance of the conductive stack 560. In some embodiments, the one or more conductive layers 526 are an instance of the conductive stack 560.

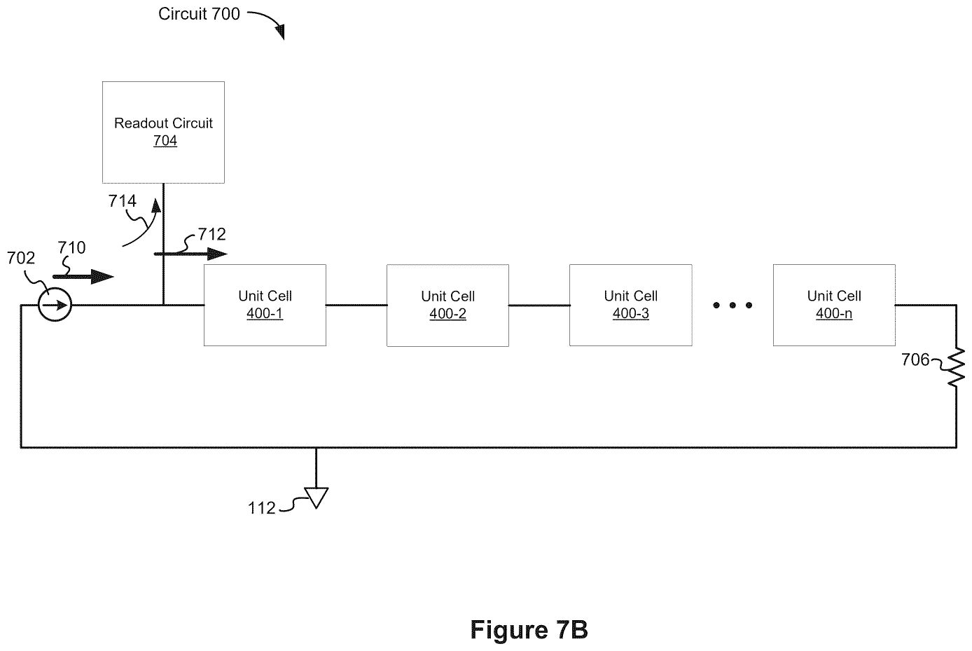

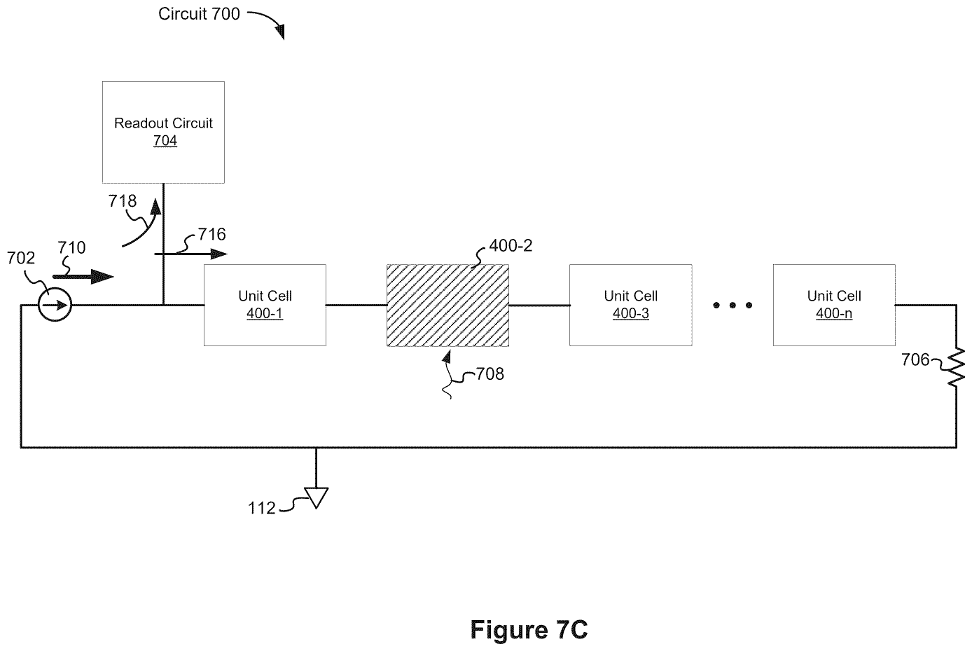

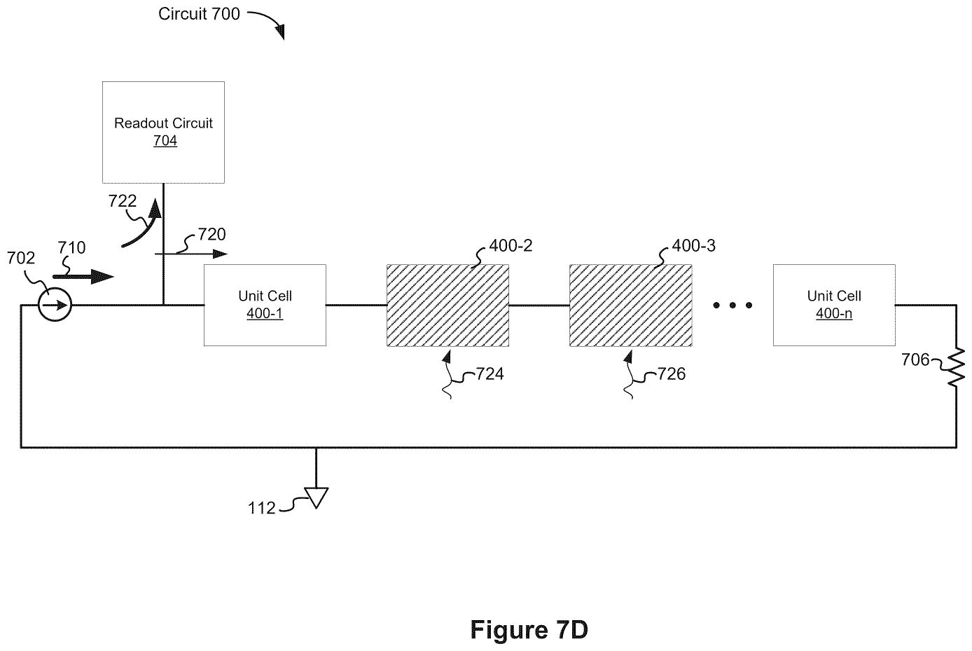

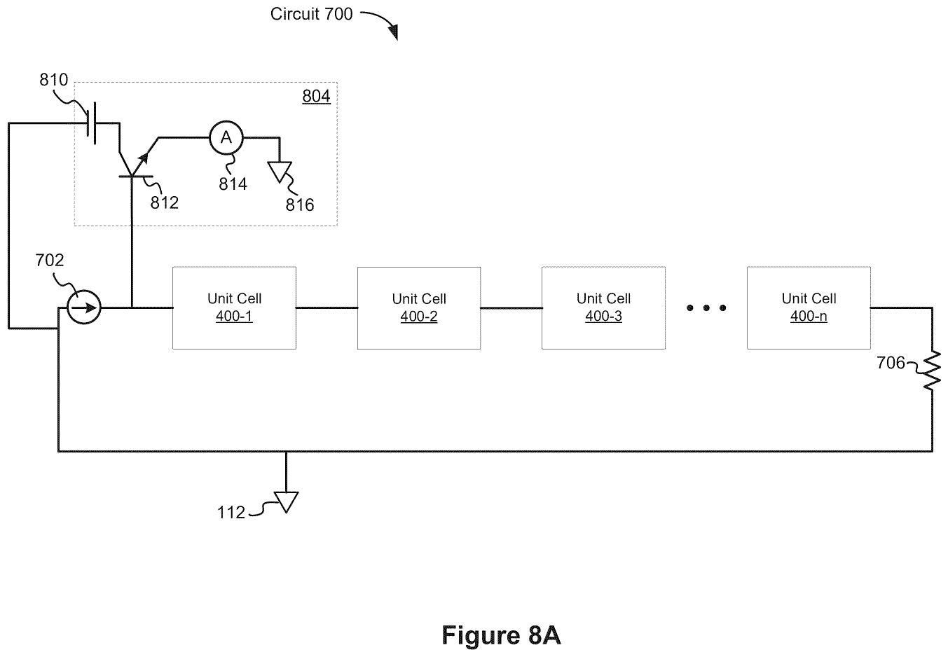

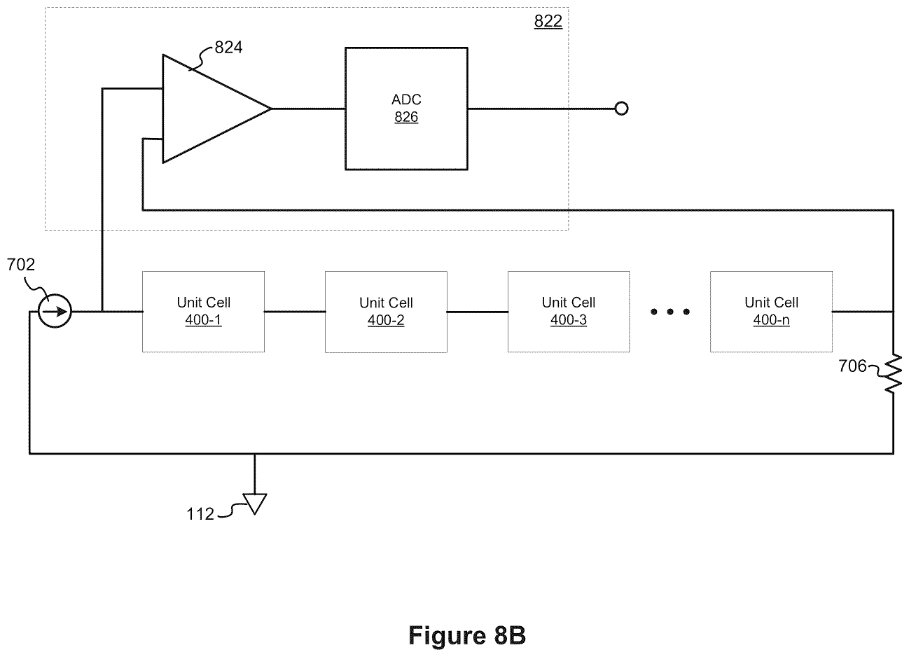

FIG. 6 shows a layout 600 for a photon number resolving detector in accordance with some embodiments. The layout 600 includes a plurality of unit cells 400 (e.g., the unit cells 400-1, 400-2, and 400-3) connected together in a series configuration with the waveguide 510. In the example of FIG. 6, each unit cell 400 includes a respective resistive region 507. In some embodiments, the photon number resolving detector includes ‘n’ unit cells. In some embodiments, ‘n’ is in the range of 10 to 1000. In some embodiments, an end 602 of the superconducting material is coupled to a current source and/or a readout circuit. In some embodiments, an end 604 of the superconducting material is coupled to an electrical ground. The unit cells 400 in FIG. 6 operate as described previously with respect to FIGS. 4 and 5A. The photon number resolving detector represented in FIG. 6 is described in more detail with respect to FIGS. 7A-7D and 8A-8B.

FIG. 7A is a schematic diagram illustrating a photon number resolving circuit 700 in accordance with some embodiments. The circuit 700 includes a plurality of unit cells 400 connected together in a series configuration, e.g., ‘n’ unit cells from unit cell 400-1 through unit cell 400-n. The circuit 700 also includes a current source 702, a readout circuit 704, a resistor 706, and the electrical ground 112. In some embodiments, the current source 702 is an instance of the current source 102. In some embodiments, the current source 702 is configured to bias the superconducting components of each unit cell 400 such that: each superconducting component is in a superconducting state in the absence of an incident photon, and a superconducting component transitions to a non-superconducting state in response to an incident photon. In some embodiments, each of the unit cells 400 in circuit 700 is an instance of unit cell 400 shown in FIG. 4, or, alternatively, an instance of circuit 120 shown in FIG. 2, excluding the current source 102. In some embodiments, each unit cell 400 has a layout as described previously with respect to FIG. 5A (e.g., coupled together as shown in FIG. 6).

FIGS. 7B-7D are prophetic diagrams illustrating a representative operating sequence of the photon number resolving circuit 700 in accordance with some embodiments. FIG. 7B shows current flow at a first time when superconducting components of each unit cell 400 are in the superconducting state. In FIG. 7B, current 710 from the current source 702 splits into current 714 flowing to the readout circuit 704 and current 712 flowing through the unit cells and the resistor 706 to the electrical ground 112 (e.g., the unit cell branch of the circuit 700). A majority of the current 710 from the current source 702 flows through the unit cell branch of the circuit in FIG. 7B, as denoted by relative thicknesses of the arrows for currents 712 and 714. The current 712 in FIG. 7B represents a majority of the current 710 from the current source 702 because the unit cell branch of the circuit has the least resistance (e.g., due to the superconducting components of each unit cell having zero resistance while in the superconducting state).

FIG. 7C shows current flow at a second time when the unit cell 400-2 is in a non-superconducting state, e.g., at least one of the superconducting components 414, 416 (see FIG. 4) of the unit cell 400-2 is in the non-superconducting state. The unit cell 400-2 is in the non-superconducting state due to the incident photon 708 being absorbed by a superconducting component of unit cell 400-2. As shown in FIG. 7C, additional current is flowing to the readout circuit 704 in response to the unit cell 400-2 being in the non-superconducting state, as denoted by relative thicknesses of the arrows for currents 716 and 718. Specifically, the current 718 flowing to the readout circuit in FIG. 7C represents more current than the current 714 flowing to the unit cells 400 in FIG. 7B because the unit cell 400-2 has increased resistance while in the non-superconducting state (e.g., increased resistance corresponding to the resistance of resistor 404, through which current flows when at least one of the superconducting components 414 and 416 is in the non-superconducting state).

FIG. 7D shows current flow at a third time when the unit cells 400-2, 400-3 are in a non-superconducting state. In FIG. 7D, the unit cell 400-2 is in the non-superconducting state due to the incident photon 724 and the unit cell 400-3 is in the non-superconducting state due to the incident photon 726 (different from incident photon 724) in accordance with some embodiments. As shown in FIG. 7D, additional current is flowing to the readout circuit 704 in response to the unit cells 400-2, 400-3 being in the non-superconducting state, as denoted by relative thicknesses of the arrows for currents 720 and 722. Specifically, the current 722 flowing to the readout circuit in FIG. 7D represents more current than the current 718 in FIG. 7C because each of the unit cells 400-2, 400-3 have increased resistance while in the non-superconducting state. As shown in FIGS. 7B-7D, an amount of current flowing to the readout circuit 704 is based on a number of unit cells 400 in the non-superconducting state. In some embodiments, in response to the amount of current flowing into the readout circuit 704, the readout circuit generates a signal indicating a number or count of photons detected by circuit 700. In this way, the circuit 700 operates as a photon number resolving circuit.

FIG. 8A is a schematic diagram illustrating a readout circuit 804 for the photon number resolving circuit 700 in accordance with some embodiments. In some embodiments, the readout circuit 804 is an instance of the readout circuit 704. The readout circuit 804 includes a capacitor 810, a transistor 812, a current source 814, and an electrical ground 816. In some embodiments, the electrical ground 816 is the electrical ground 112. In some embodiments, the resistor 706 is adapted (e.g., sized) to bias the base (sometimes called the gate) of the transistor 812 in an amplification range. In some embodiments, a working point voltage for the base (e.g., gate) of the transistor 812 is based on a resistance of the resistor 706 multiplied by the current flowing through the resistor 706 (e.g., the current 712 in FIG. 7B) when the superconducting components of all the unit cells 400 in circuit 700 are in the superconducting state. For example, the amplification range is a linear amplification range between an ‘off’ state and an ‘on’ state of the transistor 812. In some embodiments, the voltage output by transistor 812 (e.g., on the emitter of transistor 812) increases linearly for currents corresponding to the number of unit cells 400 that are in the non-superconducting state due to the absorption of incident photons. In this way, a change in current at the base (e.g., gate) of the transistor 812 (e.g., due to a unit cell 400 transitioning to a non-superconducting state) results in a change in voltage across the transistor (e.g., between the collector and emitter of the transistor 812). In accordance with some embodiments, the voltage across the transistor is converted to a current by the current source 814, e.g., the current source 814 is a voltage controlled current source (VCCS).

FIG. 8B is a schematic diagram illustrating a readout circuit 822 for the photon number resolving circuit 700 in accordance with some embodiments. In some embodiments, the readout circuit 822 is an instance of the readout circuit 704. The readout circuit 822 includes a differential amplifier 824 and an analog-to-digital converter (ADC) 826. In accordance with some embodiments, the differential amplifier 824 amplifies a voltage difference across the unit cells 400 (e.g., due to one or more unit cells 400 being in a non-superconducting state) and the ADC 826 converts the amplified voltage difference to a digital code.

In light of these principles, we now turn to certain embodiments.

(A1) In accordance with some embodiments, an electrical circuit (e.g., the circuit 120) includes: a superconducting photon detector (e.g., the superconducting component 114) that transitions from a superconducting state to a non-superconducting state in response to an incident photon (e.g., the photon 308); and a reset circuit (e.g., reset circuit 134) coupled in parallel with the superconducting photon detector, the reset circuit including a resistor (e.g., the resistor 130) and an inductor (e.g., the inductor 128 or 132) coupled together in series, where the resistor is composed of a metal layer (e.g., the conductive layer 526) and a layer of superconducting material (e.g., the superconductor layer 522). In some embodiments, the electrical circuit includes a superconducting nanowire single photon detector (SNSPD), e.g., the superconducting component 114 operates as an SNSPD. In some circumstances it is advantageous for the resistor to be composed of superconducting material and conducting material as it may allow for smaller resistor sizing and resistances as compared to conventional resistors. Additionally, smaller resistances result in smaller required inductances to maintain a same RL time constant, allowing for smaller inductor sizing in some circumstances.

(A2) The electrical circuit of A1, where: the resistor and the inductor have an RL time constant, the superconducting photon detector requires a time (T) to reset after an incident photon, and the RL time constant is at least T. For example, the superconducting photon detector requires 1 nanosecond to reset after detecting a photon, and the resistor and the inductor are sized to have an RL time constant of 2 nanoseconds. In some embodiments, the reset time (T) and the RL time constant have a same order of magnitude, e.g., T is 1 nanosecond and the RL time constant is in the range of 1 nanosecond to 5 nanoseconds. In some circumstances it is advantageous for the RL time constant to be only slightly longer than the reset time (T) so that the circuit is ready to detect a subsequent photon sooner. In some embodiments, the RL time constant has a duration that exceeds the reset time of the superconducting photon detector by no more than 10%, 25%, 50% or 100% of the reset time of the superconducting photon detector.

(A3) The electrical circuit of A1 or A2, where the electrical circuit has a resistance of less than 10 ohms at an operating temperature of the electrical circuit (e.g., a cryogenic operating temperature for the superconducting material). In some embodiments, the resistor (e.g., the resistor 130) has a resistance of less than 10 ohms and there are no other resistances in the reset path sufficient to increase the total resistance above 10 ohms. In this way, the required inductance for the RL time constant is lower than if the resistance in the reset path is greater than 10 ohms (e.g., as described with reference to FIG. 1).

(A4) The electrical circuit of any of A1-A3, where the resistor includes the metal layer in contact with the layer of superconducting material. In some embodiments, the superconducting material is composed of multiple layers and the metal layer is in contact with at least one of the multiple layers of superconducting material. In some embodiments, the metal layer is parallel with the superconducting layer and all, or a majority of, the resistance of the resistor is a proximity resistance (e.g., as shown and described with reference to FIG. 5B).

(A5) The electrical circuit of any of A1-A3, where the resistor includes a metal layer electrically coupled to the layer of superconducting material. In some embodiments, current flows from the superconducting material to the metal layer and back to the superconducting material (e.g., as shown and described with reference to FIG. 5C). In some embodiments, all, or a majority of, the resistance of the resistor is a resistance of the metal layer. In some embodiments, the metal layer comprises aluminum or titanium.

(A6) The electrical circuit of any of A1-A5, where the superconducting photon detector is composed of the layer of superconducting material (e.g., Niobium nitride). In some embodiments, the superconducting material includes a layer of Niobium nitride (NbN) between layers of Aluminum nitride (AlN). In some embodiments, the superconducting photon detector is composed of a same superconducting material as the resistor (e.g., as shown in FIG. 5A). In some circumstances it is advantageous for the superconducting photon detector and the resistor (and wiring therebetween) to be composed of the same superconducting material as it reduces fabrication complexity, allows for the components to operate in a same temperature range (e.g., a cryogenic temperature range), and reduces sizing of the electrical circuit.

(A7) The electrical circuit of any of A1-A6, where the inductor is kinetic inductance of the superconducting material. In some embodiments, all, or a majority of, the inductance of the inductor is kinetic inductance of the superconducting material (e.g., geometric inductance is negligible). In some circumstances it is advantageous for all, or a majority of, the inductance of the inductor to be kinetic inductance as it simplifies fabrication, allows for cryogenic operation, and reduces sizing of the electrical circuit.

(A8) The electrical circuit of any of A1-A7, where the electrical circuit has an inductance of less than 1 nanohenry. For example, the inductors 122, 124, 126, 128, and 132 in FIG. 2 have a combined inductance of less than 1 nanohenry and there is no other inductance in the circuit sufficient to increase the total inductance above 1 nanohenry. In some embodiments, the electrical circuit has an inductance of less than 10 nanohenry, 5 nanohenry, or 2 nanohenry (e.g., based on a resistance of the resistor and the desired RL time constant).

(B1) In accordance with some embodiments a photon number resolving circuit (e.g., the circuit 700) includes a plurality of detection circuits (e.g., the unit cells 400), each detection circuit of the plurality of detection circuits including: a superconducting photon detector (e.g., the superconducting component 414 or 416) that transitions from a superconducting state to a non-superconducting state in response to an incident photon; and a reset circuit coupled in parallel with the superconducting photon detector, the reset circuit including a resistor (e.g., the resistor 404) and an inductor (e.g., the inductor 402 or 406) coupled together in series. The photon number resolving circuit further includes a waveguide (e.g., the waveguide 510) optically coupled to the plurality of detection circuits; and a readout circuit (e.g., the readout circuit 704) electrically coupled to the plurality of detection circuits.

(B2) The photon number resolving circuit of B1, where the readout circuit is a direct readout circuit (e.g., the readout circuit 804) that converts a voltage from the plurality of detection circuits into a current (e.g., the current produced by the current source 814), and where an amplitude of the current depends on a number of detection circuits of the plurality of detection circuits in the non-superconducting state. For example, while a first number of detection circuits of the plurality of detection circuits are in the non-superconducting state (e.g., in response to detection of photons by the first number of detection circuits), an amplitude of the current depends on the first number of detection circuits of the plurality of detection circuits that are in the non-superconducting state, e.g., as illustrated in FIGS. 7B-7D.

(B3) The photon number resolving circuit of B1 or B2, where the readout circuit includes a transistor (e.g., the transistor 812), and where a base or gate of the transistor is coupled to the plurality of detection circuits and biased to operate in an amplification region. For example, the transistor is biased to operate in a linear amplification region for the number of detection circuits in the plurality of detection circuits as described above with respect to FIG. 8A.

(B4) The photon number resolving circuit of B3, further including a resistor (e.g., the resistor 706) coupled to the readout circuit and sized so as to bias the transistor in the amplification region, e.g., as described above with respect to FIG. 8A.

(B5) The photon number resolving circuit of B1, where the readout circuit includes a differential amplifier (e.g., the amplifier 824) coupled to the plurality of detection circuits, and an analog-to-digital converter (e.g., the ADC 826) coupled to the output of the differential amplifier.

(B6) The photon number resolving circuit of B5, where a first input to the differential amplifier is coupled to a first side of the plurality of detection circuits and a second input to the differential amplifier is coupled at a second side of the plurality of detection circuits so as to measure a voltage difference across the plurality of detection circuits. For example, FIG. 8B shows a first input to the differential amplifier 824 coupled to a first side of the plurality of unit cells 400 and a second input of the differential amplifier 824 coupled at a second side of the plurality of unit cells 400.

(B7) The photon number resolving circuit of any of B1-B6, further including a current source (e.g., the current source 702) coupled to the plurality of detection circuits, the current source configured to bias each superconducting photon detector such that a single incident photon causes the superconducting photon detector to transition from the superconducting state to the non-superconducting state, e.g., as shown and described above with respect to FIGS. 7B-7D.

Although some of various drawings illustrate a number of logical stages in a particular order, stages that are not order dependent may be reordered and other stages may be combined or broken out. While some reordering or other groupings are specifically mentioned, others will be obvious to those of ordinary skill in the art, so the ordering and groupings presented herein are not an exhaustive list of alternatives. Moreover, it should be recognized that the stages could be implemented in hardware, firmware, software or any combination thereof.

It will also be understood that, although the terms first, second, etc. are, in some instances, used herein to describe various elements, these elements should not be limited by these terms. These terms are only used to distinguish one element from another. For example, a first current could be termed a second current, and, similarly, a second current could be termed a first current, without departing from the scope of the various described embodiments. The first current and the second current are both currents, but they are not the same current unless explicitly stated as such.

As used herein, a “superconducting circuit” or “superconductor circuit” is a circuit having one or more superconducting materials. For example, a superconducting detector circuit is a detector circuit that includes one or more superconducting materials. As used herein, a “superconducting” material is a material that is capable of operating in a superconducting state (under particular conditions). For example, a material that operates as a superconductor (e.g., operates with zero electrical resistance) when cooled below a particular temperature (e.g., a critical temperature) and having less than a maximum current flowing through it. The superconducting materials may also operate in an “off” state where little or no current is present. In some embodiments, the superconducting materials operate in a non-superconducting state during which the materials have a non-zero electrical resistance (e.g., a resistance in the range of one thousand to ten thousand ohms). For example, a superconducting material supplied with a current greater than a threshold superconducting current for the superconducting material may transition from a superconducting state with zero electrical resistance to a non-superconducting state with non-zero electrical resistance.

As used herein, a “wire” is a section of material configured for transferring electrical current. In some embodiments, a wire includes a section of material conditionally capable of transferring electrical current (e.g., a wire made of a superconducting material that is capable of transferring electrical current while the wire is maintained at a temperature below a threshold temperature). A cross-section of a wire (e.g., a cross-section that is perpendicular to a length of the wire) optionally has a geometric (e.g., flat or round) shape or an irregular (also sometimes called a non-geometric) shape. In some embodiments, a length of a wire is greater than a width or a thickness of the wire (e.g., the length of a wire is at least 5, 6, 7, 8, 9, or 10 times greater than the width and the thickness of the wire).

The terminology used in the description of the various described embodiments herein is for the purpose of describing particular embodiments only and is not intended to be limiting. As used in the description of the various described embodiments and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

The foregoing description, for purpose of explanation, has been described with reference to specific embodiments. However, the illustrative discussions above are not intended to be exhaustive or to limit the scope of the claims to the precise forms disclosed. Many modifications and variations are possible in view of the above teachings. The embodiments were chosen in order to best explain the principles underlying the claims and their practical applications, to thereby enable others skilled in the art to best use the embodiments with various modifications as are suited to the particular uses contemplated.

What is claimed is:

1. An electrical circuit, comprising:
a superconducting photon detector that transitions from a superconducting state to a non-superconducting state in response to an incident photon; and
a reset circuit coupled in parallel with the superconducting photon detector, the reset circuit comprising a resistor (R) and an inductor (L) coupled together in series, wherein the resistor is composed of a metal layer and a layer of superconducting material.

2. The electrical circuit of claim 1, wherein the resistor and the inductor have an RL time constant, wherein the superconducting photon detector requires a time (T) to reset after an incident photon, and wherein the RL time constant is at least T.

3. The electrical circuit of claim 1, wherein the electrical circuit has a resistance of less than 10 ohms at an operating temperature of the electrical circuit.

4. The electrical circuit of claim 1, wherein the resistor comprises the metal layer in contact with the layer of superconducting material.

5. The electrical circuit of claim 1, wherein the resistor comprises the metal layer electrically coupled to the layer of superconducting material.

6. The electrical circuit of claim 1, wherein the superconducting photon detector is composed of the layer of superconducting material.

7. The electrical circuit of claim 1, wherein the inductor is kinetic inductance of the superconducting material.

8. The electrical circuit of claim 1, wherein the electrical circuit has an inductance of less than 1 nanohenry.

9. A photon number resolving circuit, comprising:
a plurality of detection circuits, each detection circuit of the plurality of detection circuits comprising:
a superconducting photon detector that transitions from a superconducting state to a non-superconducting state in response to an incident photon; and
a reset circuit coupled in parallel with the superconducting photon detector, the reset circuit comprising a resistor (R) and an inductor (L) coupled together in series;
a waveguide optically coupled to the plurality of detection circuits; and
a readout circuit electrically coupled to the plurality of detection circuits.

10. The photon number resolving circuit of claim 9, wherein the readout circuit is a direct readout circuit that converts a voltage from the plurality of detection circuits into a current, wherein an amplitude of the current depends on a number of detection circuits of the plurality of detection circuits in the non-superconducting state.

11. The photon number resolving circuit of claim 9, wherein the readout circuit comprises a transistor, wherein a base or gate of the transistor is coupled to the plurality of detection circuits and biased to operate in an amplification region.

12. The photon number resolving circuit of claim 11, further comprising a resistor coupled to the readout circuit and sized so as to bias the transistor in the amplification region.

13. The photon number resolving circuit of claim 9, wherein the readout circuit comprises a differential amplifier coupled to the plurality of detection circuits, and an analog-to-digital converter coupled to an output of the differential amplifier.

14. The photon number resolving circuit of claim 13, wherein a first input to the differential amplifier is coupled to a first end of the plurality of detection circuits and a second input to the differential amplifier is coupled at a second end of the plurality of detection circuits so as to measure a voltage difference across the plurality of detection circuits.

15. The photon number resolving circuit of claim 9, further comprising a current source coupled to the plurality of detection circuits, the current source configured to bias each superconducting photon detector such that a single incident photon causes the superconducting photon detector to transition from the superconducting state to the non-superconducting state.
